(19) United States
(12) Patent Application Publication
(10) Pub. No.: US 2014/0080255 A1
(43) Pub. Date: Mar. 20, 2014

(54) ULTRA-LOW POWER SWNT INTERCONNECTS FOR SUB-THRESHOLD CIRCUITS

(71) Applicant: Georgia Tech Research Corporation, (US)

(72) Inventors: Azad Naeemi, Atlanta, GA (US); Muhammad Omer Jamal, Atlanta, GA (US)

(73) Assignee: Georgia Tech Research Corporation, Atlanta, GA (US)

(21) Appl. No.: 13/891,009

(22) Filed: May 9, 2013

Related U.S. Application Data
(63) Continuation of application No. 12/793,831, filed on Jun. 4, 2010, now abandoned.

(51) Int. Cl. H01L 23/00

(52) U.S. Cl. CPC H01L 24/83
USPC 438/107

(57) ABSTRACT

Ultra-low power single metallic single-wall-nano-tube (SWNT) interconnects for sub-threshold circuits are provided. According to some embodiments, an interconnect structure for use in electronic circuits can generally comprise a first substrate, a second substrate, and an interconnect. The first substrate can be spaced apart from the second substrate. The interconnect is preferably a single wall carbon nanotube (SWNT) interconnect. The SWNT interconnect can be disposed between the first and second substrates to electrically connect the substrates. The substrates can form parts of electrical components (e.g., a transistor, processor, memory, filters, etc.) operating in a subthreshold operational state. Other aspects, features, and embodiments are claimed and described.

### CROSS-REFERENCE TO RELATED APPLICATIONS

This application is a continuation application of U.S. Non-Provisional application Ser. No. 12/793,831, filed on 4 Jun. 2010, which is incorporated herein by reference in its entirety as if fully set forth below.

### FEDERAL RESEARCH STATEMENT

This invention was made with government funds support under Contract No. HR0011-07-3-0002, awarded by DARPA. The U.S. Government has certain rights in this invention.

### TECHNICAL FIELD

Embodiments of the invention relate generally to nano-interconnects for circuits, and more specifically to, ultra-low power single metallic single-wall-nano-tube (SWNT) interconnects for sub-threshold circuits.

### BACKGROUND

Carbon nanotubes (CNTs) have widely discussed in the literature and varying methods have been devised to produce CNTs. CNTs have been adapted for various types of uses. One use that many are researching includes using CNTs as interconnects for integrated electronic-type circuits. Typically carbon nanotubes used as interconnects are manufactured as having various number of walls, including single wall carbon nanotube interconnects.

Single Wall Carbon nanotube interconnects (SWNTs) seem promising but have limitations, both fundamental and practical. The resistance of single SWNTs is quite large and to overcome this issue, dense SWNT bundles are needed. There has been little progress in wafer-level fabrication of horizontal bundles of densely packed nanotubes.

What is needed therefore are interconnects and interconnect fabrication methods that address these issues. Embodiments of the present invention are directed to providing solutions to meet these challenges.

### SUMMARY OF EXEMPLARY EMBODIMENTS

In theory, SWNTs show great promise as interconnects for electronics systems. Progress in fabricating aligned horizontal bundles of densely-packed SWNTs and reliable contacts with electrical connections to all tubes within the bundles has been limited. These breakthroughs are key in outperforming Cu interconnects. Although improvements have been reported for catalyst activity, grown SWNT bundles are still very sparse.

Various reports discuss current efforts and typically these efforts have drawbacks. There are reports of growing about 87% metallic SWNT bundle however the density is still quite low after the separation. There has been major progress in growing aligned SWNTs on sapphire and transferring them to other substrates. This wafer-level process avoids several manufacturability issues with CNTs such as the need for high temperatures that are not compatible with CMOS back-end-of-the-line processes. The process can also be repeated to increase the density of nanotubes. In this method, however, isolated nanotubes are obtained which are useful for device and sensor applications not for interconnect applications. Recently, it has also been reported that using platinum decoration, the average electrical resistivity of aligned arrays of SWNT interconnects can be decreased by 45%. The platinum nano-clusters decoration can convert semiconducting SWNTs into metallic ones, and can improve the conductance of metallic tubes. This process fabricates highly organized, scalable and aligned SWNT array interconnect structures using template-guided fluidic assembly method. The process is reported to be CMOS-compatible and scalable to wafer-levels.

Emerging applications of electronic circuits, such as implantable medical devices and sensor nodes, have motivated investigation of circuit design in an operational mode known as the subthreshold region. As is typically known and defined, this is where a transistor's supply voltage, V_{dd}, is lower than threshold voltage, Vₜₕ. These circuits are suitable for ultra-low power applications where low operating frequencies can be tolerated.

While speed and power dissipation of these circuits are highly dependent on interconnect capacitance, interconnect resistance is largely dominated by extremely large transistor resistances. This provides a novel opportunity for single SWNTs to be used as interconnects to lower interconnect capacitance and avoid the manufacturing difficulties involved with SWNT bundles. Embodiments of the present invention provide single SWNTs that can be used as interconnects and achieve major improvements in delay and power dissipation of subthreshold circuits. It should be understood, however, that embodiments of the present invention can be used in other applications where use of subthreshold operational ranges is desired.

Broadly speaking, embodiments of the present invention can include electrical packages having one or more electronic circuits operating in a subthreshold operational state. Electrical packages can comprise a first electrical pad spaced apart from a second electrical pad. Pads can be used as attachment, bonding, or coupling surfaces. The pads can be components of distinct electrical components disposed within an electrical device. The electrical packages can also include a single wall carbon nanotube interconnect. The interconnect can be disposed between and electrically couple the first and second electrical pads. Preferably, at least one of the distinct electrical components is in a subthreshold operational state. Use the term electrical package is meant to include any type of electronics circuitry device that is traditionally assembled in an IC package form for use with an electronics device.

Electrical package embodiments can also include additional features. For example, the distinct electrical components include logic gates (e.g., an inverter). Logic gates (and also electrical components) can include driver circuitry capable of providing voltage to an interconnect. Distinct electrical components can also include a first transistor and a second transistor each having a number of transistor electrodes. A nanotube interconnect can electrically couple a selected pair of the transistor electrodes. This enables the first and second transistors to be electrically coupled. Preferably transistors are both in a subthreshold operational state when used in accordance with embodiments of the present invention.

Electrical package embodiments may also include additional features. For example, a single wall carbon interconnect may be disposed at an arrangement ranging from vertical to horizontal to electrical pads for connection purposes. Also distinct electrical components can be spaced apart semiconductor devices, with one pad forming part of one semiconductor device and a pad forming part of another semiconductor device. A single wall carbon nanotube interconnect can be used to electrically couple spaced apart semiconductor devices. In some embodiments, a single wall carbon nanotube interconnect can be replaced with a graphene nanoribbon interconnect.

Other embodiments of the present invention include interconnect structures. These structures can be implemented for use in an electrical component having one or more electrical circuits with an interconnect structure electrically coupling electrical circuits operating in a subthreshold state. Interconnect structures can generally include a single wall carbon nanotube interconnect disposed between a first electrode component and a second electrode component. The single wall carbon nanotube can have two opposed ends with one end connected to the first electrode and another end connected to the second electrode. One of the first electrode or the second electrode components preferably form part of an electrical circuit operating in a subthreshold operational state. The first electrode component can be located on a device separate from the second electrode component

Interconnect structures according to embodiments of the present invention can also include additional features. For example, interconnect structures can be made of carbon nanotubes (e.g., single wall tubes or concentric-multi wall tubes) and graphene nanoribbons (e.g., one or more sheets of graphene nanoribbon). Graphene nanoribbon interconnects can have a capacitance less than εᵣ×40×10⁻¹⁸ F/μm, where εᵣ is the dielectric constant of the insulator surrounding the nanoribbon interconnect. Single wall carbon nanotube interconnects can have a capacitance less than εᵣ×25×10⁻¹⁸ F/μm, where εᵣ is the dielectric constant of the insulator surrounding the nanotube. Insulators can be made from many materials including silicon dioxide, air, organic, and non-organic materials. In some embodiments, interconnects can be positioned substantially horizontally relative to both the first electrode and the second electrode for bonding to electrodes of electrical components.

Embodiments of the present invention also include improved electrical component system having one or more semiconductor-based components. These embodiments can include a first electrical circuit component and a second electrical circuit component operating in a subthreshold state. A single wall carbon nanotube and/or a graphene nanoribbon interconnect can be disposed in electrical communication with the first and second electrical circuit components to electrically interconnect said components. The first and second electrical circuit components can be distinct transistors or logic gates located on a semiconductor-wafer or within an IC package. System embodiments can also include a third electrical circuit component operating in a subthreshold state. A single wall carbon nanotube and/or graphene nanotube interconnect can electrically couple one or both of the first and second electrical circuit components to the third electrical circuit component.

System embodiments can also include additional features. For example, single wall carbon nanotube interconnects can have a capacitance less than εᵣ×25×10⁻¹⁸ F/μm and graphene nanoribbon interconnects has a capacitance less than εᵣ×40×10⁻¹⁸ F/μm, where εᵣ is the dielectric constant of the insulator surrounding the nanotube interconnect or the nanoribbon interconnect. Also systems can include a substrate to carry a first set and a second set of circuit components. The first set of circuit components can form a first electrical device on the substrate and the second set of circuit components can form a second electrical device on the substrate. Interconnects used with embodiments of the present invention can have a diameter ranging from about 0.7 nm to about 3 nm.

Other aspects and features of embodiments of the present invention will become apparent to those of ordinary skill in the art, upon reviewing the following description of specific, exemplary embodiments of the present invention in concert with the figures. While features of the present invention may be discussed relative to certain embodiments and figures, all embodiments of the present invention can include one or more of the features discussed herein. While one or more embodiments may be discussed as having certain advantageous features, one or more of such features may also be used with the various embodiments of the invention discussed herein. In similar fashion, while exemplary embodiments may be discussed below as system or method embodiments it is to be understood that such exemplary embodiments can be implemented in various devices, systems, and methods.

### BRIEF DESCRIPTION OF FIGURES

FIG. 1 illustrates a schematic diagram of a conventional copper interconnect disposed between substrates.

FIG. 2 illustrates a schematic diagram of a single wall nanotube interconnect in accordance with some embodiments of the present invention.

FIG. 3 graphically illustrates relative delay enhancement due to SWNT interconnect for various technology nodes in accordance with some embodiments of the present invention.

FIG. 4 graphically illustrates relative EDP of copper and SWNT interconnects for various technology nodes when a n-FET channel width to length ratio is =5.

FIG. 5 graphically illustrates relative delay enhancement offered by monolayer GNR interconnects of various widths compared to the reference copper interconnects when drivers are inverters with n-FET size W/L=5.

FIG. 6 graphically illustrates relative EDP enhancement offered by monolayer GNR interconnects of various widths compared to the reference copper interconnects when drivers are inverters with n-FET size W-L=5.

FIG. 7 graphically illustrates relative delay enhancement offered by multilayer GNR interconnects of various widths compared to the reference copper interconnects when drivers are inverters with n-FET size W/L=5.

FIG. 8 graphically illustrates relative EDP enhancement offered by multilayer GNR interconnects of various widths compared to the reference copper interconnects when drivers are inverters with n-FET size W/L=5.

FIG. 9 illustrates an exemplary electrical package comprising components interconnected with interconnect structures according to some embodiments of the present invention.

### DETAILED DESCRIPTION OF PREFERRED & ALTERNATIVE EMBODIMENTS

To facilitate an understanding of the principles and features of the various embodiments of the invention, various illustrative embodiments are explained below. As will be explained, embodiments of the present invention provide improved and advantageous interconnects. Advantageously, embodiments of the present invention enable fast and efficient operation of electronic circuits in subthreshold operational range. Some embodiments can be used in electronic circuits forming part of electronic devices including, but not limited to, implants, medical devices, biomedical implants, cardiac implants, cardiac rhythm management devices, pacemakers, defibrillators, neurological stimulators, gastric bands, RFID tags, wireless sensor networks and transceivers, wireless communication devices, hearing aids, and cochlear devices. It should be understood that this list is exemplary and not exhaustive. Indeed, embodiments of the present invention can be used as nanotubes to connect an output of one logic gate to an input of another logic gate (e.g., from a drain of one transistor to a gate of another transistor). Due to their small size, embodiments of the present invention can also be embedded with electrical packages (e.g., integrated circuit packages) for connecting substrate wafers.

### General Design & Operation Design Theory

Prior to discussing specific exemplary embodiments of the invention background on transistor operation theory and interconnect operation is warranted. The basic equation for modeling the output current of a transistor in the subthreshold regime is given by:

$${I}_{SUB} = {I}_{0} {e}^{\frac{{V}_{GS} - {V}_{t}}{n {V}_{TH}}} ( 1 - {e}^{\frac{- {V}_{DS}}{{V}_{TH}}} )$$

where I₀=μ₀C_{OX}W/L(n−1)Vₜₕ², n is the subthreshold slope factor (1+C_{D}/D_{OX}), C_{D} and C_{OX} are depletion and oxide capacitances, respectively, and V_{TH} is the thermal voltage (kT/q).

Since gate tunneling current is a strong function of V_{DD}, it can be neglected for subthreshold operation. Leakage components like gate induced drain leakage (GIDL) and pn-junction leakage also become insignificant.

For copper interconnects, minimum-size wires with a thickness-to-width ratio of 2 are considered. The International Technology Roadmap for Semiconductors (ITRS) projections for copper resistivity, ρ, which take into account surface and grain boundary scatterings of electrons are used to calculate per unit length resistance of copper wires. For 22, 18, and 14 nm technology nodes, resistance per unit length values of 62.1, 103.4 and 209 Ω/μm are calculated, respectively.

Capacitance per unit length, C_{w}, is calculated using electrostatic simulator RAPHAEL. The dielectric constant is taken to be 2.2 based on ITRS projections. The average copper capacitance, which corresponds to the case when neighboring wires are quiet, is found to be 140 aF/μm. The value of this capacitance is independent of technology generation provided the dielectric constant and interconnect aspect ratios remain constant.

The equivalent circuit model for SWNTs presented in is used to calculate delay of SWNT interconnects. For 1 nm diameter SWNTs, the mean free path is taken to be 1 μm and contact resistance, R_{c}, is conservatively assumed to be 20 kΩ. The average electrostatic capacitance per unit length of SWNTs, c_{E} , has been obtained from simulations in RAPHAEL. Quantum capacitance of 400 aF/μm which is in series with the electrostatic capacitance, and kinetic inductance of 4 nH/μm has also been included in calculations. Per unit length capacitances of SWNTs with a diameter of 1 nm are obtained to be 24.4 aF/μm for the 22 nm node, 25.2 aF/μm for the 18nm node and 27 aF/μm for the 14 nm node which are more than 5× smaller than that of copper wires with the capacitance per unit length of 140 aF/μm.

Also the capacitive coupling between neighboring SWNT interconnects is significantly smaller than that of copper wires. Capacitive coupling defined as the ratio of mutual capacitance to total capacitance determines crosstalk noise. For SWNTs, this capacitive coupling is 0.095, 0.098 and 0.1 at the 22, 18, and 14 nm nodes, respectively, as compared to 0.36 for copper wires.

For graphene nanoribbons (GNRs), compact physics based circuit models have been used. Analysis is done with both monolayer and multilayer ribbons and edge roughness effects have been included. The Fermi energy has been assumed to be 0.4 eV for GNRs and edge backscattering probability is taken as P=0.2. For monolayer GNRs, the capacitances per unit length are obtained to be 44, 36 and 34 aF/μm for 11, 5.5 and 4.4 nm wide ribbons, respectively. Similarly, for multilayer GNR with five layers of graphene, the capacitances per unit length are found to be 47, 39 and 37 aF/μm, respectively.

Thus, and as described herein, embodiments of the present invention provide improved performance by focusing on low capacitance values associated with individual SWNTs and nanoribbons as opposed to bundling these to reduce resistance in concert with operating electrical components in subthreshold operating regimes.

### Exemplary SWNT/GNR Interconnect Implementations

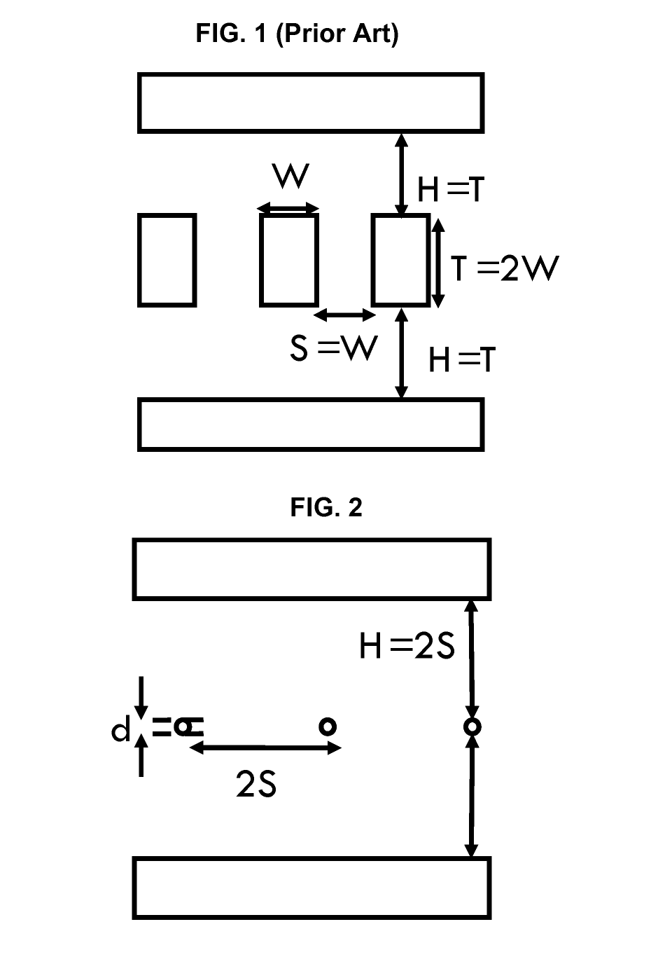

Turning now to the figures, FIGS. 1 and 2 illustrate schematic designs of interconnect implementations. FIG. 1 shows a conventional Cu interconnect and FIG. 2 shows a SWNT interconnect according to embodiments of the present invention. The inventors have discovered that utilizing a SWNT interconnect in an electrical device operating in subthreshold operational ranges provides advantageous results. These advantages include fast and efficient operation. As a result, SWNT interconnects have desired usages in some electronics applications. Namely, for devices designed for operation in subthreshold ranges.

The schematic designs shown in FIGS. 1-2 generally show the dimension differences between conventional Cu interconnects and interconnect structures in accordance with embodiments of the present invention. As discussed herein, interconnect structures according to the present invention can include carbon nanotubes (e.g., single wall carbon nanotubes, concentric multi-wall carbon nanotubes having small diameters) and graphene nanoribbons. It is currently preferred that utilized carbon nanotubes are single wall carbon nanotubes since these types of nanotubes provide advantageous features when utilized with electrical components operating in subthreshold operational states.

In devising their inventions, the inventors have, and as discussed above, modeled conventional Cu interconnects for comparison against SWNT and GNR interconnects. To compare the potential performances of copper, SWNT, and GNR interconnects, a supply voltage of 100 mV, is used for the 22, 18 and 14 nm technology nodes, and the diameter of SWNTs is assumed to be 1 nm. The sensitivity of the results to supply voltage is later discussed. The threshold voltages for these technology nodes are taken as 202 mV, 193 mV and 190 mV, respectively, based on the ITRS projections. The performance metrics selected are delay and energy-delay-product (EDP). To model the 50% delay with a circuit simulator like SPICE, the transistors are modeled by non-ideal voltage-dependent current sources described by (1) and interconnects are represented by distributed RC networks. For an inverter with an n-FET channel width-to-length ratio of 5, the speed enhancement offered by SWNT interconnects is plotted versus length in gate pitch in FIG. 3. The gate pitch is calculated based on the ITRS projections for the number of transistors and an average transistor per logic gate of 4.

In FIG. 3, it can be seen that single SWNT interconnects can offer up to five times improvement in the delay of subthreshold circuits even though their resistance is more than two orders of magnitude larger than that of copper wires. This is due to the extremely large output resistances of transistors in the subthreshold regime and the very low capacitance of SWNT interconnects. It can also be seen that the advantage of SWNT interconnects in terms of delay over copper wires is maximized at interconnect lengths around 200 gate pitches. For short interconnects, increasing the length increases the ratio of interconnect capacitance to transistor capacitance; hence SWNTs offer larger overall capacitance reduction. However once interconnects become too long, the resistances of SWNTs become comparable with or even larger than those of their drivers. Hence there is a drop in performance enhancement that SWNT interconnects can offer beyond roughly 200 gate pitch lengths.

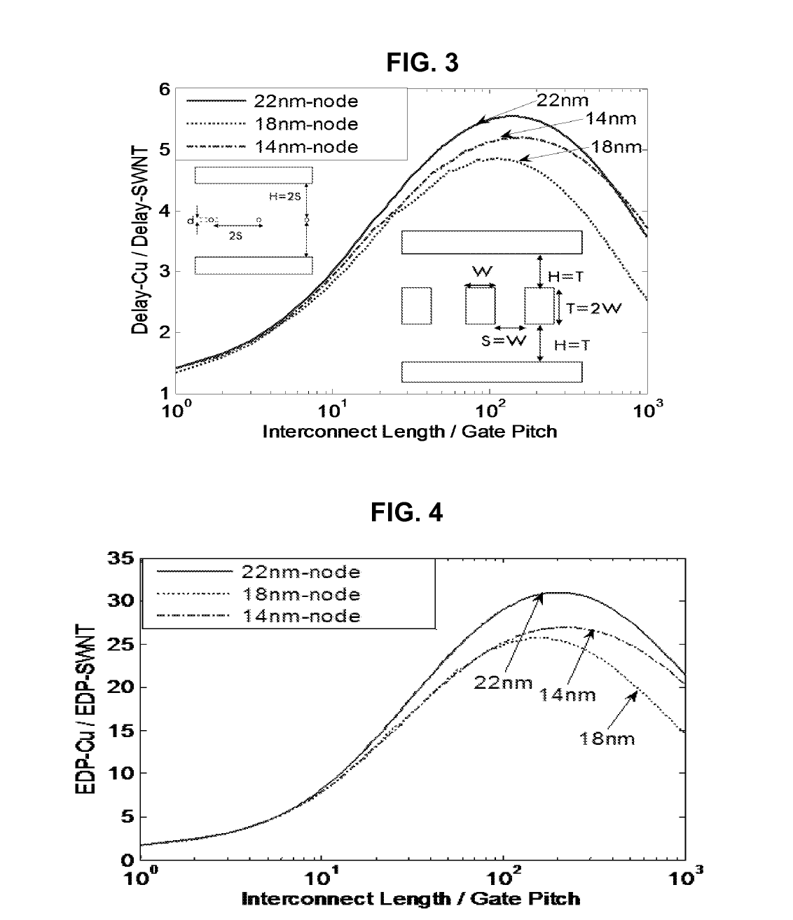

The improvement in delay that SWNT interconnects offer is in addition to reduction of interconnect capacitance and hence energy per binary switching operation. This is demonstrated in FIG. 4, where the EDP enhancements that SWNTs can offer is plotted versus interconnect length. Depending on the length, SWNTs can offer up to 30 times reduction in the EDP.

The delay enhancement that SWNT interconnects can offer depends on the driver size. Increasing the driver size, lowers the output resistance and increases the driver capacitance both of which lower the delay improvement that SWNT interconnects may offer. The maximum speed improvement offered by SWNT interconnects in FIG. 1 is around 5.5 times, and doubling the driver size lowers this improvement to 4.5 times. Likewise, at higher supply voltages the output resistance is lower and the delay enhancement offered by SWNTs decreases as shown by the inset table in FIG. 4. The small variation in results for various technology nodes is mainly because of the difference in leakage currents at these technology nodes.

Due to its large kinetic inductance, even an ideal SWNT interconnect driven by a transistor in the strong inversion regime can have a delay larger than a minimum-size copper wire because of the large signal travel time. However, in the case of subthreshold circuits, driver resistance is so large that the RC charging-time becomes quite dominant relative to the wave propagation time in SWNTs. For instance, for an inverter with an n-FET channel width-to-length ratio of 5 implemented at the 22 nm node and driving a 100 gate-pitch long interconnect, the RC time constant is 3.5 ns whereas the time-of-flight is only 21 ps. Kinetic Inductance, therefore, can have a negligible effect in analyzing SWNT interconnects used for sub-threshold circuits. Simulations showed that the inclusion of kinetic inductance results in less than 10% increase in delay values.

Due to large resistance of isolated SWNTs, bundles of densely-packed SWNTs have been proposed to be used as interconnects. Manufacturing such bundles, however, at the wafer-level and making reliable low-resistance connections to the majority of nanotubes within bundles are formidable tasks. Single isolated SWNTs can be used as interconnects in subthreshold circuits because of their very low capacitance. The large resistances of SWNT interconnects are dominated by the very large output resistances of transistors in the subthreshold regime. Compared to copper interconnects with a typical aspect ratio of 2, SWNT interconnects are up to 5 times faster and dissipate about 6 times less energy per binary switching operations. These performance and energy advantages offered by single SWNT interconnects combined with recent progress in wafer-level fabrication of aligned SWNTs makes them a promising candidate for low-power nanoelectronic circuits.

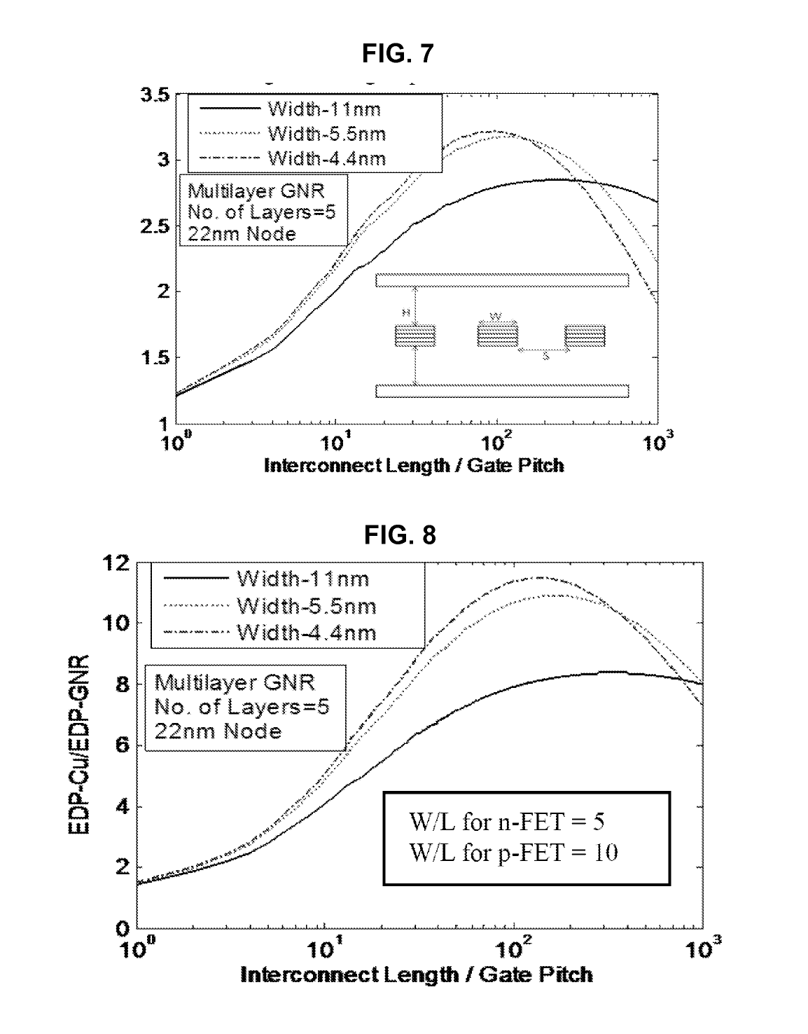

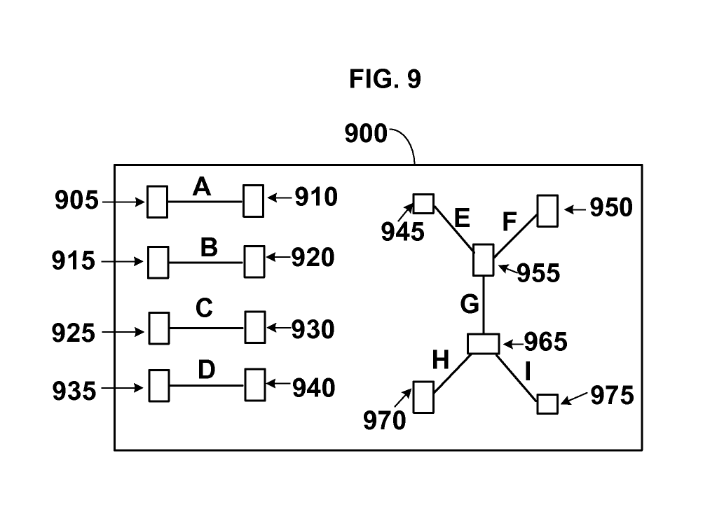

For an inverter with an n-FET channel width-to-length ratio of 5, the speed enhancement and the EDP reduction offered by monolayer GNR interconnects compared to minimum feature sized copper wires is plotted versus length in gate pitch in FIGS. 7 and 8, respectively. The technology node is taken to be 22 nm and various GNR widths have been considered. The results show improvements as compared to copper interconnects. However, the performance enhancement is less than SWNT. One can reduce GNR width while keeping interconnect pitch constant to further lower interconnect capacitance. This, however, causes a significant rise in GNR resistance and the advantage obtained from the reduced capacitance is not adequate to compensate the resistance increase. For 4.4 nm monolayer ribbon, the resistance becomes 160 KΩ/μm. It can also be seen that the length at which performance enhancement is maximized decreases as GNR width decreases. To reduce the resistance, multilayer graphene can be used while capacitance increases by less than 8% compared to monolayer GNRs. The delay and EDP reductions offered by 5-layer GNRs are plotted in FIGS. 9 and 10, respectively. Comparing FIGS. 3 and 4 and FIGS. 5 and 10 demonstrates that SWNTs offer larger performance enhancements and EDP reductions. However, GNR interconnects may be more manufacturable.

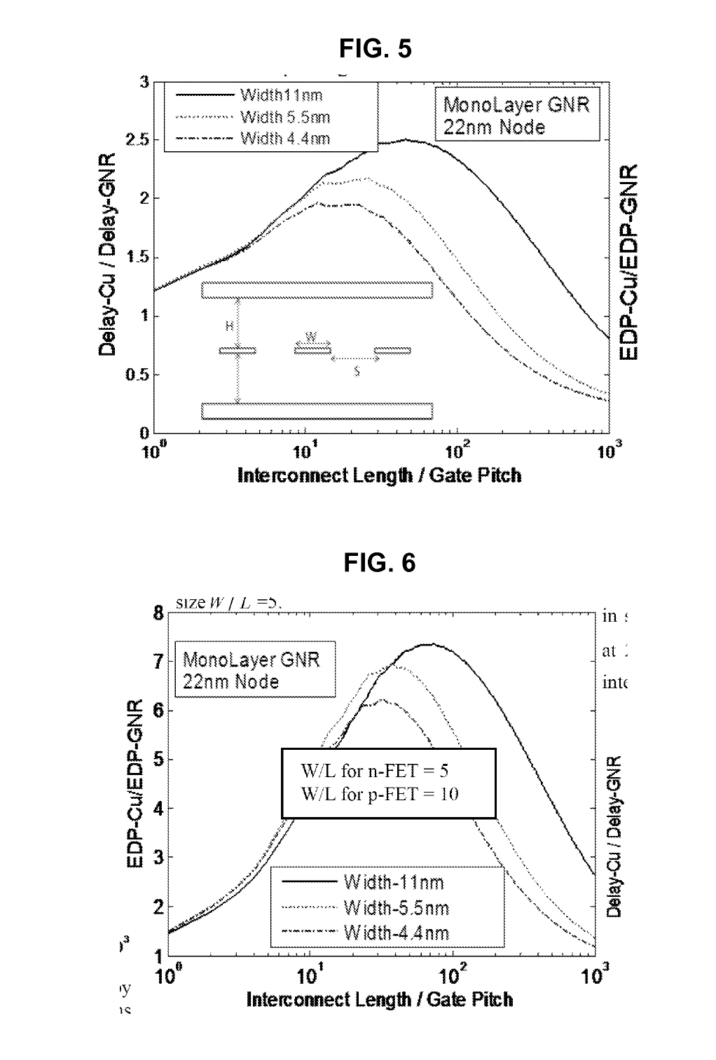

FIG. 5 illustrates an exemplary electrical package 500 comprising components interconnected with interconnect structures according to some embodiments of the present invention. The electrical package 500 can be many types of electrical devices that include one or more electrical components. For example, the electrical package 500 can be an integrated circuit package including a number of electrical components. The electrical package 500 can be disposed in may electrical devices including implants, medical devices, biomedical implants, cardiac implants, cardiac rhythm management devices, pacemakers, defibrillators, neurological stimulators, gastric bands, RFID tags, wireless sensor networks and transceivers, wireless communication devices, hearing aids, and cochlear devices.

As shown, the electrical package 500 can include a number of sub-items. These sub-items include electrical components 505-570 and interconnects A-I. The electrical components 505-570 can be many types of components configured to work in an electrical system. These components include processors, logic gates, transistors, semiconductor-based devices, and the like. In some embodiments, the electrical components 505-570 may include bond pads or substrate surfaces for interfacing with the interconnect structures A-I. As shown, the interconnect structures A-I can be used to interconnect various electrical components 505-570. The interconnect structures A-I may be formed by carbon nanotubes (e.g., single wall carbon nanotubes) or graphene nanoribbons. The inventors currently prefer to use the interconnect structures A-I to interconnect components on a one-level wafer.

The electrical package 500 and it sub-items may have additional features. Indeed, for example, interconnect structures preferably have advantageous capacitances. For example, utilized carbon nanotubes can have a capacitance less than εᵣ×25×10⁻¹⁸ F/μm and utilized graphene nanoribbons can have a capacitance less than εᵣ×40×10⁻¹⁸ F/μm, where εᵣ is the dielectric constant of the insulator surrounding the nanotube. Regarding insulators, many types of insulators may be used. As a few examples, insulator materials can include silicon dioxide, organic, or non-organic low-k dielectric materials. Even air in some cases may be used as an insulator. Any of these insulator materials can be used for nanotube or nanoribbon interconnects. Generally, the lower the dielectric constant is, the lower the interconnect capacitance is going to be, and hence a better performance can be achieved.

It should be understood that FIG. 5 is only an exemplary figure and that an actual package may contain many more logic gates, transistors, interconnects. For example, the package could contain as many electrical components 505-570 and interconnects A-I as desired or as required by a design consideration. The actual number of these items could number in the hundreds or even in the thousands. In addition, the actual geometric configuration and placement of electrical components 505-570 and interconnects A-I on a substrate may vary as desired.

### Conclusion

The embodiments of the present invention are not limited to the particular formulations, process steps, and materials disclosed herein as such formulations, process steps, and materials may vary somewhat. The terminology employed herein is used for the purpose of describing exemplary embodiments only and the terminology is not intended to be limiting since the scope of the various embodiments of the present invention will be limited only by the appended claims and equivalents thereof. The descriptions are exemplary and yet other features and embodiments exist. While embodiments of the invention are described with reference to embodiments, those skilled in the art will understand that variations and modifications can be effected within the scope of the appended claims. The scope of the various embodiments of the present invention should not be limited to the above discussed embodiments. The full scope of the invention and all equivalents should only be defined by the following claims and all equivalents.

1. A method of using an electrical device, comprising:
providing a first electrical pad of a first electrical component of the electrical device;
providing a second electrical pad of a second electrical component of the electrical device, the second electrical pad spaced apart from the first electrical pad, the second electrical component distinct from the first electrical component;
electrically coupling the first and second electrical pads with at least one of a single wall carbon nanotube interconnect and a graphene nanoribbon interconnect disposed between the first and second electrical pads; and
operating the at least one of the first electrical component and the second electrical component in a subthreshold operational state.

2. The method of claim 1, wherein at least one of the first and second electrical components comprises a logic gate.

3. The method of claim 1, wherein the first electrical component comprises a first transistor and the second electrical component comprises a second transistor, each of the first and second transistors having a plurality of transistor electrodes, and wherein the at least one of a single wall carbon nanotube interconnect and a graphene nanoribbon interconnect electrically couples a selected pair of the transistor electrodes to electrically couple the first and second transistors.

4. The method of claim 3, wherein the operating step comprises operating both the first and second transistors in a subthreshold operational state.

5. The method of claim 1, wherein the electrically coupling step comprises disposing the at least one of a single wall carbon nanotube interconnect and a graphene nanoribbon interconnect at an arrangement ranging from vertical to horizontal to both the first electrical pad and second electrical pad.

6. The method of claim 1, wherein the first electrical component comprises a first semiconductor device and the second electrical component comprises a second semiconductor device, the first electrical pad forming part of the first semiconductor device and the second electrical pad forming part of the second semiconductor device, wherein the electrically coupling step comprises electrically coupling the first and second semiconductor devices with the at least one of a single wall carbon nanotube interconnect and a graphene nanoribbon interconnect.

7. A method of electrically coupling electrical circuits, comprising:
disposing at least one of a single wall carbon nanotube interconnect and a graphene nanoribbon interconnect between a first electrode and a second electrode, the at least one of a single wall carbon nanotube interconnect and a graphene nanoribbon interconnect having a first end and an opposed second end, the first end connected to the first electrode and the second end connected to the second electrode, wherein at least one of the first electrode and the second electrode form part of an electrical circuit; and
operating the electrical circuit in a subthreshold operational state.

8. The method of claim 7, wherein the first electrode is located on a device separate from the second electrode.

9. The method of claim 7, wherein the at least one of a single wall carbon nanotube interconnect and a graphene nanoribbon interconnect is a graphene nanoribbon interconnect.

10. The method of claim 9, wherein the graphene nanoribbon interconnect has a capacitance less than εᵣ×40×10⁻¹⁸ F/μm, where εᵣ is the dielectric constant of an insulator surrounding the nanoribbon interconnect.

11. The method of claim 7, wherein the disposing step comprises positioning the at least one of a single wall carbon nanotube interconnect and a graphene nanoribbon interconnect substantially horizontally relative to both the first electrode and the second electrode.

12. The method of claim 7, further comprising disposing a second at least one of a single wall carbon nanotube interconnect and a graphene nanoribbon interconnect between the first electrode and a third electrode, the second at least one of a single wall carbon nanotube interconnect and a graphene nanoribbon interconnect having a first end and an opposed second end, the first end connected to the first electrode and the second end connected to the third electrode, such that the second at least one of a single wall carbon nanotube interconnect and a graphene nanoribbon interconnect electrically couples the first electrode and the third electrode.

13. The method of claim 7, wherein the at least one of a single wall carbon nanotube interconnect and a graphene nanoribbon interconnect is a single wall carbon nanotube interconnect having a capacitance less than εᵣ×25×10⁻¹⁸ F/μm, where εᵣ is the dielectric constant of the insulator surrounding the nanotube.

14. A method of coupling electrical circuit components, comprising:
providing a first electrical circuit component;
providing a second electrical circuit component;
disposing at least one of a single wall carbon nanotube interconnect and a graphene nanoribbon interconnect between the first and second electrical circuit component to electrically couple the first electrical circuit component to the second electrical circuit component; and
operating the first and second electrical circuit components in the subthreshold operational state.

15. The method of claim 14, wherein the first and second electrical circuit components comprise distinct transistors or logic gates.

16. The method of claim 14, further comprising:
providing a third electrical circuit component
disposing a second at least one of a single wall carbon nanotube interconnect and a graphene nanoribbon interconnect between at least one of the first and second electrical circuit components and the third electrical circuit component to electrically couple at least one of the first and second electrical circuit components to the third electrical circuit component; and
operating the third electrical circuit component in the subthreshold operational state.

17. The method of claim 14, wherein the at least one of a single wall carbon nanotube interconnect and a graphene nanoribbon interconnect comprises at least one of a single wall carbon nanotube interconnect having a capacitance less than εᵣ×25×10⁻¹⁸ F/μm and a graphene nanoribbon interconnect having a capacitance less than εᵣ×40×10⁻¹⁸ F/μm, where εᵣ is the dielectric constant of the insulator surrounding the nanotube interconnect or the nanoribbon interconnect.

18. The method of claim 14, further comprising providing a substrate to carry a first and second set of circuit components, the first set of circuit components comprising the first electrical circuit component and the second electrical circuit component, and wherein the first set of circuit components forms a first electrical device on the substrate and the second set of circuit components forms a second electrical device on the substrate.

19. The method of claim 14, wherein the at least one of the single wall carbon nanotube interconnect and the graphene nanoribbon interconnect has a diameter ranging from about 0.7 nm to about 3 nm.

20. The method of claim 14, wherein the at least one of the single wall carbon nanotube interconnect and the graphene nanoribbon interconnect is physically independent of the first and second electrical circuit components.
